(19) United States
(12) Patent Application Publication
(10) Pub. No.: US 2023/0320139 A1
(43) Pub. Date: Oct. 5, 2023

(54) ORGANIC ELECTROLUMINESCENT DEVICES WITH IMPROVED OPTICAL OUT-COUPLING EFFICIENCIES

(71) Applicants: Applied Materials, Inc., Santa Clara, CA (US); National Taiwan Universtiy, Taipei (TW)

(72) Inventors: Chung-chia CHEN, San Jose, CA (US); Wan-Yu LIN, Taipei City (TW); Hyunsung BANG, Alzenau (DE); Lisong XU, Santa Clara, CA (US); Gang YU, Santa Barbara, CA (US); Byung-Sung KWAK, Mountain View, CA (US); Robert Jan VISSER, Menlo Park, CA (US); Chung-Chih WU, Taipei City (TW); Hoang Yan LIN, Keelung City (TW); Guo-Dong SU, Taipei City (TW); Wei-Kai LEE, Taipei City (TW); Yi-Jiun CHEN, Taipei (TW); Ting-Sheng HSU, Kaohsiung City (TW); Po-Hsiang LIAO, Taichung City (TW); Wei-Cheng LIN, Taipei (TW)

(21) Appl. No.: 18/021,856

(22) PCT Filed: Sep. 21, 2020
(86) PCT No.: PCT/US2020/051820

§ 371 Date: Feb. 17, 2023

(51) Int. Cl. H10K 59/122; H10K 59/80; H10K 59/131

(52) U.S. Cl. CPC H10K 59/122; H10K 59/879; H10K 59/80524; H10K 59/131; H10K 2102/101

(57) ABSTRACT

Embodiments of the present disclosure generally relate to electroluminescent devices, such as organic light-emitting diodes, and displays including electroluminescent devices. In an embodiment is provided an electroluminescent device that includes a pixel defining layer, an organic emitting unit disposed over at least a portion of the pixel defining layer, and a filler layer disposed over at least a portion of the organic emitting unit, wherein a refractive index of the pixel defining layer is lower than a refractive index of the filler layer, and wherein the refractive index of the pixel defining layer is lower than a refractive index of one or more layers of the organic emitting unit. In another embodiment is provided a display device that includes a substrate, a thin film transistor formed on the substrate, an interconnection electrically coupled to the thin film transistor, and an electroluminescent device electrically coupled to the interconnection.

### CROSS-REFERENCE TO RELATED APPLICATIONS

This application is a National Stage filing of International Appl. No. PCT/US2020/051820, filed Sep. 21, 2020, which is herein incorporated by reference in its entirety.

### BACKGROUND

### Field

Embodiments of the present disclosure generally relate to electroluminescent devices and displays including electroluminescent devices. More specifically, embodiments described herein relate to organic light-emitting diode structures and their applications.

### Description of the Related Art

An organic light-emitting diode (OLED) is an electroluminescent device which emits light when driven by current. Due to their light weight, flexibility, wide viewing angle, and fast response time, OLEDs have become increasingly important in display technology. In typical OLED structures, there is significant efficiency loss between internal quantum efficiency (IQE) and external quantum efficiency (EQE). As such, a significant amount of emitting light becomes trapped inside the OLED display, and the emitting light escapes along the horizontal direction (in a parallel direction to the substrate) due to a mismatch of optical parameters in the OLED and the functional layers. For example, less than about 25% EQE has been achieved by existing device configurations even when the IQE is 100%. In addition to optical energy loss, the leakage light can be extracted into air in adjacent pixels reducing the display sharpness and contrast.

Although structures to improve the EQE, such as micro-lens, surface textures, scattering, embedded low-index grids, embedded grating/corrugation, embedded photonic crystals, and high-refractive-index substrates can provide enhancement of the EQE, these structures have been problematic in many aspects. For example, such structures may not be compatible with specific OLED structures, can downgrade the display resolution and image quality, can require difficult and expensive fabrication, can be wavelength dependent, and/or can be suitable for bottom-emitting OLEDs only. In addition, the use of such structures may lead to crosstalk or image blurring that would degrade their display resolution and image quality.

There is a need for new and improved OLED structures devices that overcome one or more deficiencies of conventional OLED structures and devices.

### SUMMARY

Embodiments of the present disclosure generally relate to electroluminescent devices and displays including electroluminescent devices. More specifically, embodiments described herein relate to organic light-emitting diode structures and their applications.

In an embodiment is provided an electroluminescent device that includes a pixel defining layer, an organic emitting unit disposed over at least a portion of the pixel defining layer, the organic emitting unit comprising one or more layers, and a filler layer disposed over at least a portion of the organic emitting unit. A refractive index of the pixel defining layer is lower than a refractive index of the filler layer and lower than a refractive index of the one or more layers of the organic emitting unit.

In another embodiment is provided an electroluminescent device that includes a pixel defining layer disposed over at least a portion of a bottom electrode, an organic emitting unit disposed over at least a portion of the pixel defining layer, a top electrode disposed over at least a portion of the organic emitting unit, the organic emitting unit comprising one or more layers, and a filler layer disposed over at least a portion of the top electrode. A refractive index of the pixel defining layer is lower than a refractive index of the filler layer and lower than a refractive index of the one or more layers of the organic emitting unit. The refractive index of the filler layer is greater than or equal to the refractive index of the one or more layers of the organic emitting unit. The top electrode comprises a transparent conductive oxide material, a semi-transparent conductive oxide material, a metal, a metal alloy, or a combination thereof.

In another embodiment is provided a display device that includes a substrate, a thin film transistor formed on the substrate, an interconnection electrically coupled to the thin film transistor, and an electroluminescent device electrically coupled to the interconnection. The electroluminescent device includes a pixel defining layer, an organic emitting unit disposed over at least a portion of the pixel defining layer, the organic emitting unit comprising one or more layers, and a filler layer disposed over at least a portion of the organic emitting unit. A refractive index of the pixel defining layer is lower than a refractive index of the filler layer and lower than a refractive index of the one or more layers of the organic emitting unit.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a bottom-emitting OLED structure.

FIG. 2 is a top-emitting OLED structure.

FIG. 3A is a cross-section of an example OLED structure according to at least one embodiment of the present disclosure.

FIG. 3B is a cross-section of an example OLED structure according to at least one embodiment of the present disclosure.

FIG. 4 is a cross-section of an example organic emitting unit according to at least one embodiment of the present disclosure.

FIG. 5 is a cross-section of an example active matrix organic light emitting diode (AMOLED) structure according to at least one embodiment of the present disclosure.

FIG. 6A is an example PDL side-wall reflectivity for S-polarized light and P-polarized light versus varying wavelength and angle of incidence according to at least one embodiment of the present disclosure.

FIG. 6B shows examples that indicate the reflectivity of a PDL side wall with various fillers of different refractive indices according to at least one embodiment of the present disclosure.

FIG. 7 illustrates light paths in an example pixel structure according to at least one embodiment of the present disclosure.

FIG. 8A is a graph showing luminous intensity versus initial emission angle (θ₁) of an example OLED device according to at least one embodiment of the present disclosure.

FIG. 8B summarizes example light extraction efficiencies (ηₑₓₜ, in percent) versus different bank angles and different filler refractive indices according to at least one embodiment of the present disclosure.

FIG. 9A is an example of parameters of a pixel dimension according to at least one embodiment of the present disclosure.

FIG. 9B is a graph of light extraction efficiencies versus different height and width of example pixel structures with a fixed bank angle θ_{B}=60° according to at least one embodiment of the present disclosure.

FIG. 9C is a graph illustrating the relationship of example aspect ratios of a pixel and light extraction efficiency with a fixed pixel width W₁=3 μm according to at least one embodiment of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to electroluminescent devices and displays including electroluminescent devices. More specifically, embodiments described herein relate to organic light-emitting diode structures and their applications. OLED structures with improved light extraction efficiency and improved external quantum efficiency (EQE) are disclosed herein. Briefly, the new and improved OLED structures have a pixel-defining layer (PDL), a filler material, an organic emitting unit, and a top electrode (e.g., a cathode) that includes a transparent conductive oxide material, a semi-transparent conductive oxide material, a metal, a metal alloy, or a combination thereof in a top-emitting configuration. The PDL is a material (e.g., an organic material) having a lower refractive index than both the filler material and one or more layers of the organic emitting unit. The reflection mechanism of the OLED device described herein is based on, at least, a total internal reflection (TIR) effect. As described in more detail hereinbelow, the use of a PDL material having a lower refractive index than the materials above it in the OLED stack (e.g., the filler material, the organic emitting unit, and the top electrode), accentuates and increases the reflection of the waveguided light from the PDL-organic emitting unit interface toward the extraction surface/interface. The high-refractive-index contrast between the PDL and the layers above the PDL (e.g., an organic emitting unit, filler layer, and the top electrode) leads to a total internal reflection of the incident light and thereby allows incident light to reflect back into the organic emitting unit toward the extraction direction. This high-refractive-index contrast can be further accentuated by adding an additional material, e.g., layer/structure, disposed over at least a portion of the PDL having a higher refractive index than the OLED stack. Alternatively, the additional material, e.g., layer/structure, disposed over at least a portion of the PDL has a lower refractive index than that of the PDL. Such an embodiment can be used when a low refractive index PDL material is, e.g., difficult to obtain.

Some conventional OLED structures address the waveguide loss mechanism by employing a reflective metal surface that acts like a mirror to reflect obliquely or horizontally transporting light which cannot be extracted out of an OLED originally. In contrast to such conventional OLED structures, the OLED structures described herein employ a low-refractive-index PDL without the use of an additional reflective mirror. Eliminating the use of the reflective mirror can simplify manufacturing by removing the deposition and patterning operations to make the reflective mirror during OLED fabrication. Moreover, even without the reflective mirror, the OLED structures described herein have EQE enhancement. Accordingly, the light leakage and efficiency losses are mitigated by the OLED structures and devices described herein. Relative to conventional OLED devices and structures, the OLED devices and structures described herein can allow for better performance without additional structures and can be suitable for all OLED structures (e.g., top-emitting OLED and bottom-emitting OLED).

In addition, some conventional OLED structures use a photonic crystal to improve light extraction. However, the characteristic of a photonic crystal can be highly wavelength dependent. Accordingly, three kinds of photonic crystals are needed for red, green, and blue subpixels. The OLED structures described herein do not have such limitations. Moreover, some approaches for improving light extraction are only suitable for bottom-emission OLEDs. In contrast, the OLED structures described herein are suitable for both top- and bottom-emission OLED structures.

OLEDs are two-terminal thin film structures with a stack of organic layers including a light emitting organic layer sandwiched between two electrodes. At least one of the electrodes is transparent or semi-transparent, allowing emitted light to pass through. In typical OLED structures, there is significant efficiency loss between internal quantum efficiency (IQE) and external quantum efficiency (EQE). As such, a significant amount of emitting light becomes trapped inside the OLED display. The emitting light can also escape along the horizontal direction (in a parallel direction to the substrate) due to a mismatch of optical parameters in, e.g., the OLED and the functional layers. For example, less than about 25% EQE has been achieved by existing device configurations even when the IQE is 100%. In addition to optical energy loss, the leakage light can be extracted into air in adjacent pixels reducing the display sharpness and contrast.

A root cause of light loss in conventional OLED devices is the fact that the light is generated in a high-refractive-index material and has to be transmitted to air which has a low refractive index (n=1). If the incident angle is larger than the critical angle, the light experiences total internal reflection and could escape from the edge of the device and/or is transformed into heat. The light lost causes lower efficiency, and the lower efficiency means that the device is driven harder to get the same brightness. As a result, the lifetime and/or reliability of the device is reduced. Due to the large index mismatch and the number of interfaces in conventional OLED structures, optical out-coupling efficiency is not maximized. The light loss is further illustrated below in conventional OLED structures, which are classified into bottom-emitting OLEDs or top-emitting OLEDs based on the direction of the light emission relative to the substrate.

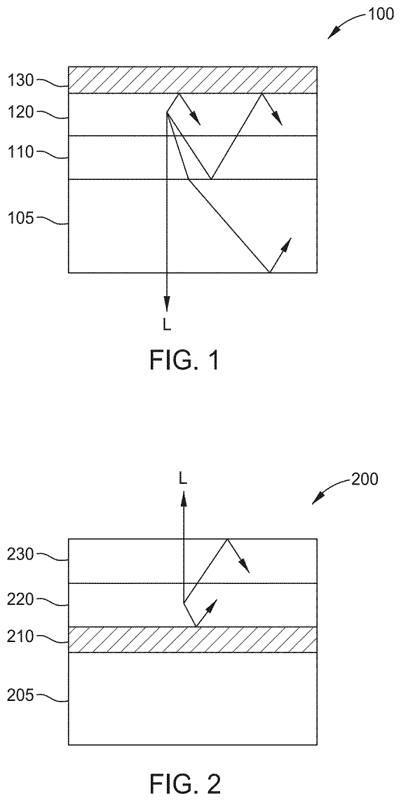

FIG. 1 shows a conventional bottom-emitting OLED structure 100. Bottom-emitting OLEDs emit through the transparent or semi-transparent substrate 105. The conventional bottom-emitting OLED structure 100 is typically composed of a single or multiple organic material layers 120 stacked between a top reflective electrode 130 and a transparent or semi-transparent electrode 110. Combinations of materials for electrodes, carrier-transport layers (e.g., hole-transport layers (HTL), electron-transport layers (ETL)), and emission layers (EML) can provide IQEs of nearly 100%. In the conventional bottom-emitting OLED structure 100, the refractive indices of the various materials cause a significant portion of internally-generated light with larger angles to be confined in the device by total internal reflection at the electrode-substrate interface and not enter the substrate for out-coupling into air. For the light entering the transparent or semi-transparent substrate 105, due to higher refractive indices (n) of transparent substrates (e.g., n is about 1.5 for glass substrates) than that of air, again a significant portion of light with larger angles will be confined in the substrate by total internal reflection at the substrate-air interface and will not be out-coupled into air. As such, in conventional bottom-emitting OLED structures 100, optical out-coupling efficiencies are generally limited to only 20-25%.

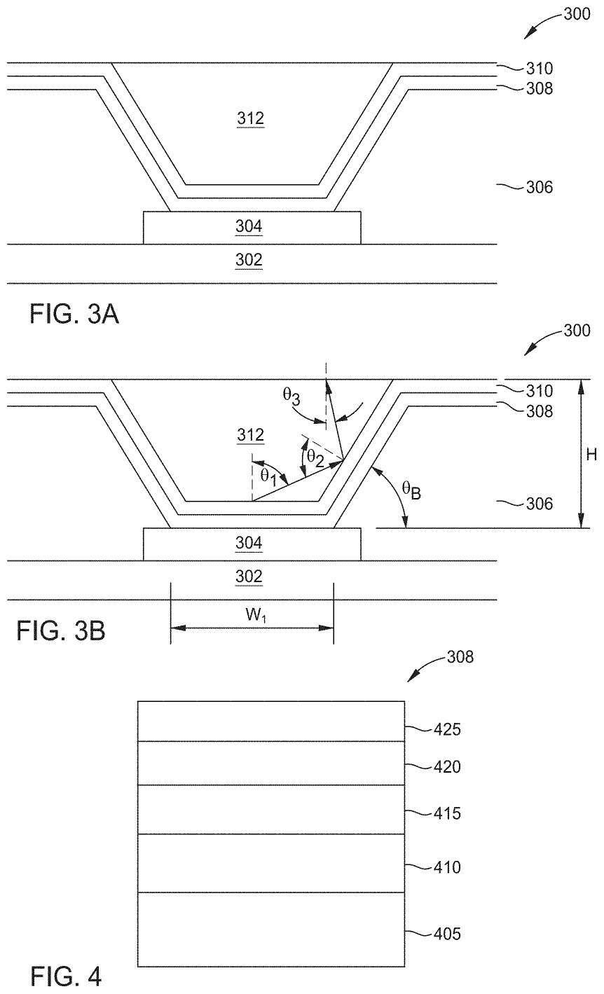

FIG. 2 shows a conventional top-emitting OLED structure 200. Top-emitting OLEDs emit opposite the substrate direction. The top-emitting OLED structure 200 includes a substrate 205 such as glass or plastic, a bottom reflective electrode 210, organic layer(s) 220, and a transparent (or semi-transparent) electrode 230 such as an indium tin oxide (ITO), a metal alloy (e.g., Mg:Ag), or a thin metal, as shown in FIG. 2. In some cases, the transparent (or semi-transparent) electrode 230 may be further over-coated with a transparent passivation or capping layer. Due to the higher refractive indices of organic layers (typically n≥1.7), transparent electrodes (typically n≥1.8), and/or transparent passivation or capping layers than that of air, a significant portion of internally generated light is confined in the device by total internal reflection at the device-air interface and cannot be out-coupled to air as shown in FIG. 2. Therefore, in typical top-emitting OLED structures, optical out-coupling efficiencies are generally also limited. Therefore, in order to achieve high-efficiency, power-saving OLED displays, the optical out-coupling efficiencies should be raised by out-coupling the otherwise trapped OLED light. Accordingly, and in some embodiments, OLED structures described herein below with reference to FIGS. 3-5 have improved optical out-coupling efficiencies over conventional OLED structures.

Embodiments described herein also overcome the EQE challenge and other challenges of conventional OLED structures and devices. The OLED structures and devices described herein can include a high-refractive-index contrast between the PDL and the layers above the PDL (e.g., an organic emitting unit, filler layer, and the top electrode). This high contrast leads to a total internal reflection of the incident light (higher the contrast, lower the critical angle of TIR), allowing incident light to reflect back into the organic emitting unit toward the extraction direction. In some embodiments, the OLED structures include a low-index PDL (e.g., n is about 1.6 or less), an organic emitting unit having a refractive index that is greater than a refractive index of the PDL, and a filler layer that has a refractive index that is greater than or equal to refractive indices of the layers of an organic emitting unit.

Although embodiments described herein are shown for top-emitting OLEDs, bottom-emitting OLEDs are contemplated. Similar principles including the high index contrast between the layers can apply for bottom-emitting OLED arrangements.

FIG. 3A shows a cross-section of an example OLED structure 300 according to at least one embodiment of the present disclosure. The example OLED structure 300 is a top-emitting OLED. The example OLED structure 300 includes a substrate 302. The substrate 302 can be any suitable material such as glass (rigid or flexible), plastic, metal foil such as Al foil or Cu foil, polymer (such as polyethylene terephthalate (PET), polyethylene naphthalate (PEN), and polyimide (PI), or a combination thereof. A bottom electrode 304 (e.g., an anode), such as a reflective electrode, is disposed over at least a portion of the substrate 302. The bottom electrode 304 can be a combination of a highly transparent (or semi-transparent) material with good conductivity and high reflectivity. When the bottom electrode functions as an anode, the bottom electrode 304 can possess a higher work function to ease the hole injection from the bottom electrode 304 into a hole injection layer of the OLED stack. Non-limiting examples of materials for the bottom electrode 304 include one or more oxides, one or more metals, one of more metal alloys, or a combination thereof, such as Ag, Al, Mo, indium tin oxide (ITO), indium zinc oxide (IZO), fluorine-doped tin oxide (FTO), doped zinc oxide, or a combination thereof. In some examples, a bottom electrode 304 comprising ITO/Ag/ITO can be used. In at least one embodiment, the bottom electrode 304 can be a distributed Bragg reflector (DBR) combined with one or more conductive materials. DBRs comprise stacks of high-refractive-index material(s) and low-refractive-index material(s). In suitable designs, DBRs can be highly reflective even when fabricated from two or more transparent dielectric materials. The DBR can be electrically non-conductive. When using an electrically non-conductive DBR, the DBR can be combined with certain conductive materials which are mentioned above to form the bottom electrode.

The OLED structure further includes a PDL 306 disposed over at least a portion of the substrate and/or disposed over at least a portion of the bottom electrode 304. The PDL 306 is one or more layers of material that defines a pixel region of an OLED structure. The PDL 306 provides isolation such that each pixel can be turned on separately. The PDL 306 is also used to define the OLED emission area and/or for planarization of the incoming substrate's topography. During fabrication, the PDL 306 can be blanket-coated on top of the bottom electrode 304 and a subsequent lithography process can make openings in the PDL 306, thereby providing the OLED emission area. The PDL 306 can also be blanket-coated on the substrate 302.

In some embodiments, the PDL 306 includes one or more materials that have a high electrical resistance and/or that are electrically insulating. Non-limiting examples of materials that can be used in the PDL 306 include any suitable material that can be integrated into OLED fabrication, such as polymers, photoresists, resins, acrylics, dielectric materials, or a combination thereof. One suitable material includes fluorinated resins. In some embodiments, the PDL 306 has a refractive index that is about 1.6 or less, such as from about 1.0 to about 1.4 or such as from about 1.1 to about 1.3, at a wavelength or wavelength range of the light emitted from the electroluminescent area (e.g., UV, near infrared, and visible, such as about 380 nm to about 780 nm). In at least one embodiment, the PDL 306 has a refractive index (n) that is or ranges from n₁ to n₂ at a wavelength or wavelength range of the light emitted from the electroluminescent area, where each of n₁ and n₂ is independently about 1.0, about 1.1, about 1.2, about 1.3, about 1.4, about 1.5, or about 1.6, so long as n₂>n₁. In some embodiments, a refractive index of the PDL 306 layer can be lower than a refractive index of the electroluminescent area.

The example OLED structure 300 further includes an organic emitting unit 308. The organic emitting unit 308 has a first surface (e.g., a bottom surface), a second surface that lies at an angle relative to the first surface, and a third surface (e.g., a top surface) parallel or substantially parallel to the first surface. Non-limiting examples of materials that can be used in the organic emitting unit 308 include any suitable material that can be integrated into OLED fabrication, such as organic materials. The organic emitting unit 308 includes one or more layers.

In some embodiments, the one or more layers of the organic emitting unit 308 have a refractive index that is about 1.3 or more, such as from about 1.3 to about 2.4, such as from about 1.5 to about 2.2, such as from about 1.6 to about 1.9 or from about 1.8 to about 2.0 at a wavelength or wavelength range of the light emitted from the electroluminescent area (e.g., UV, near infrared, and visible, such as about 380 nm to about 780 nm). In at least one embodiment, the organic emitting unit 308 has a refractive index that is or ranges from n₃ to n₄ at a wavelength or wavelength range of the light emitted from the electroluminescent area, where each of n₃ and n₄ is independently about 1.3, about 1.4, about 1.5, about 1.6, about 1.7, about 1.8, about 1.9, about 2.0, about 2.1, about 2.2, about 2.3, or about 2.4, so long as n₄>n₃.

The organic emitting unit 308 is disposed over at least a portion of the PDL 306. The organic emitting unit 308 is also disposed over at least a portion of the bottom electrode 304. The example OLED structure 300 further includes a top electrode 310 (e.g., cathode) disposed over at least a portion of the organic emitting unit 308. In some embodiments, the top electrode 310 has appropriate conductivity and transparency. Non-limiting examples of materials for the top electrode 310 can include one or more metals, one or more alloys of metals, one or more oxides, one or more transparent or semitransparent materials, or a combination thereof. For example, transparent conductive oxides (e.g., indium tin oxide (ITO) or indium zinc oxide (IZO)), Ag, Al, Mo, fluorine-doped tin oxide (FTO), doped zinc oxide, or a combination thereof can be used.

The example OLED structure 300 further includes a filler layer 312 disposed over at least a portion of the top electrode 310. The filler layer 312 can be a light index-matching layer. That is, the filler layer 312 can have a refractive index that is greater than or equal to refractive indices of the layers of an organic emitting unit 308. The filler layer 312 can also have a refractive index that is greater than the PDL 306. The filler layer 312 can avoid total internal reflection and extract light out of the OLED. As such, the filler layer 312 can act as a light-transporting or waveguiding media to guide the light into the reflective interface or extracted out. In some embodiments, the filler layer 312 includes one or more materials that possess a low to zero absorption (e.g., an extinction coefficient of k<0.1, such as k˜0) in the wavelength or wavelength range of the light emitted from the electroluminescent area. Non-limiting examples of materials that can be used in the filler layer 312 include any suitable material that can be integrated into OLED fabrication, such as organic materials, inorganic materials, resins, or a combination thereof. The filler layer 312 can include a composite such as a colloidal mixture where the colloids are high-refractive-index inorganic materials such as TiO₂. In some embodiments, the filler layer 312 has a refractive index that is about 1.6 or more, such as from about 1.8 to about 2.4, such as from about 1.8 to about 1.9, from about 1.9 to about 2.0, or from about 2.0 to about 2.2 at a wavelength or wavelength range of the light emitted from the electroluminescent area (e.g., UV, near infrared, and visible, such as about 380 nm to about 780 nm). In at least one embodiment, the filler layer 312 has a refractive index that is or ranges from n₅ to n₆ at a wavelength or wavelength range of the light emitted from the electroluminescent area, where each of n₅ and n₆ is independently about 1.6, about 1.7, about 1.8, about 1.9, about 2.0, about 2.1, about 2.2, about 2.3, about 2.4, or about 2.5, so long as n₆>n₅.

Generally, the example OLED structure 300 can be fabricated in the following manner. The bottom electrode 304 can be deposited on the substrate by, e.g., lithography. In active-matrix display, there is a wire connection to connect the OLED bottom electrode to a thin film transistor (TFT) through a via hole. After the bottom electrode 304 is formed, the PDL 306 can then be deposited. For a photoresist-type PDL, the PDL can be blanket-coated on the bottom electrode and then patterned by lithography. After the PDL opening is formed by lithography, the organic layers can be deposited in sequence. Typically, the organic layers can be deposited under vacuum by thermal evaporation. In addition, the organic layers, as well as the top electrode 310 can be deposited over the pixel with or without patterning such that the organic layers and top electrode 310 are extended up to the bank upper edge.

FIG. 3B shows the example OLED structure 300 with various angles, width (W₁), and a height (H) according to at least one embodiment of the present disclosure. As shown in FIG. 3B, W₁ is the pixel opening which is the bottom electrode 304 width not covered by the PDL, and H is the height extending from the upper edge of the filler layer 312 to the top edge of the bottom electrode 304.

In some embodiments, the angle of the PDL (Θ_{B}), which is the intersection angle of the PDL with the bottom electrode 304, is from about 40° to about 70°, such as from about 45° to about 65°, such as from about 50° to about 55°. In at least one embodiment, the angle of the PDL is or ranges from Θ_{B1} to Θ_{B2}, where each of OBS to Θ_{B2} is independently about 40°, about 41°, about 42°, about 43°, about 44°, about 45°, about 46°, about 47°, about 48°, about 49°, about 50°, about 51°, about 52°, about 53°, about 54°, about 55°, about 56°, about 57°, about 58°, about 59°, about 60°, about 61°, about 62°, about 63°, about 64°, about 65°, about 66°, about 67°, about 68°, about 69°, or about 70°, as long as Θ_{B2}>Θ_{B1}.

In at least one embodiment, the H/W₁ ratio is from about 0.01 to about 5, such as from about 0.1 to about 4, such as from about 0.25 to about 1.

In at least one embodiment, the filler layer 312 has a refractive index that is or ranges from n₅ to n₆ at a wavelength or wavelength range of the light emitted from the electroluminescent area, where each of n₅ and n₆ is independently about 1.6, about 1.7, about 1.8, about 1.9, about 2.0, about 2.1, about 2.2, about 2.3, about 2.4, or about 2.5, so long as n₆>n₅.

FIG. 4 shows a cross-section of an example organic emitting unit 308 according to at least one embodiment of the present disclosure. The organic emitting unit 308 can be disposed over at least a portion of a bottom electrode 304. A non-limiting description of the bottom electrode is provided above with reference to FIG. 3A. When the bottom electrode is an anode, the bottom electrode 304 is positively charged to inject holes (e.g., absence of electrons) into the organic emitting unit, e.g., organic emitting unit 308. The organic emitting unit 308 comprises a plurality of organic layers including a hole injection layer (HIL) 405 disposed over at least a portion of the bottom electrode 304 (not shown), a hole transport layer (HTL) 410 disposed over at least a portion of the HIL 405, an emission layer (EML) 415 disposed over at least a portion of the HTL 410, an electron transport layer (ETL) 420 disposed over at least a portion of the EML 415, and an electron injection layer (EIL) 425 disposed over at least a portion of the ETL 420. The HIL 405 eases the injection of holes from the bottom electrode 304 into the organic emitting unit 308. The HTL 410 supports the transport of holes across it so the holes can reach the EML 415. The HTL 410 can be an organic material that possesses good hole mobility. In top-emission OLED, the thickness of the various organic layers of the organic emitting unit 308 can be adjusted to meet the parameters of the cavity. The thickness of the HTL 410 can be adjusted in order to adjust the total thickness of the organic emitting unit 308. The EML 415 is where the electrical energy is converted into light. The ETL 420 supports the transport of electrons across it so they can reach the EML 415. The EIL 425 eases the injection of electrons from the top electrode 310 into the organic emitting unit 308 when the top electrode is the cathode.

In some embodiments, the organic emitting unit 308 further includes a hole blocking layer and/or an electron blocking layer. In such embodiments, the hole blocking layer can be disposed between the EML 415 and the ETL 420; the electron blocking layer can be disposed between the HTL 410 and the EML 415; and/or the electron blocking layer can be disposed between the HIL 405 and the EML 415.

In some embodiments, an additional structure (e.g., one or more high-refractive-index layers) can be disposed over at least a portion of the PDL 306 to further accentuate the index contrast against the PDL. The organic emitting unit 308 would then be disposed over the additional structure. The additional high-refractive-index layer(s) can have a refractive index that is greater than the refractive index of the layer(s) below it, thereby accentuating the difference in the index of refraction between the PDL 306 and the additional structure, leading to a greater TIR effect. This additional structure can be used in applications where, e.g., the materials for the filler layer 312 and the organic emitting unit 308 are limited and/or where a high-refractive-index filler layer 312 may not be suitable for high volume deposition. In such cases, then, an additional structure on the PDL 306 can be used to increase the refractive-index contrast.

Embodiments described herein also generally relate to display devices such as AMOLED devices. In an AMOLED display comprising multiple display elements, the OLED pixels are defined by an array of patterned bottom electrodes, each of them being connected with a pixel driver that generally includes one or more thin film transistors (TFT), metal routing lines, and capacitors. An example pixel driver for an OLED device can include a switch transistor connected with a scanning line, a data line, a current regulating transistor (sometimes called a power TFT) connected with the OLED emitter, and a storage capacitor connected with the gate of the current regulator and the drain of the switch transistor. More complex pixel driving circuits can be adopted for improving display uniformity and operation stability. As a result, the pixel driver may compete with the emission element inside the pixel area that the bottom-emission displays may be limited to certain pixel pitch size.

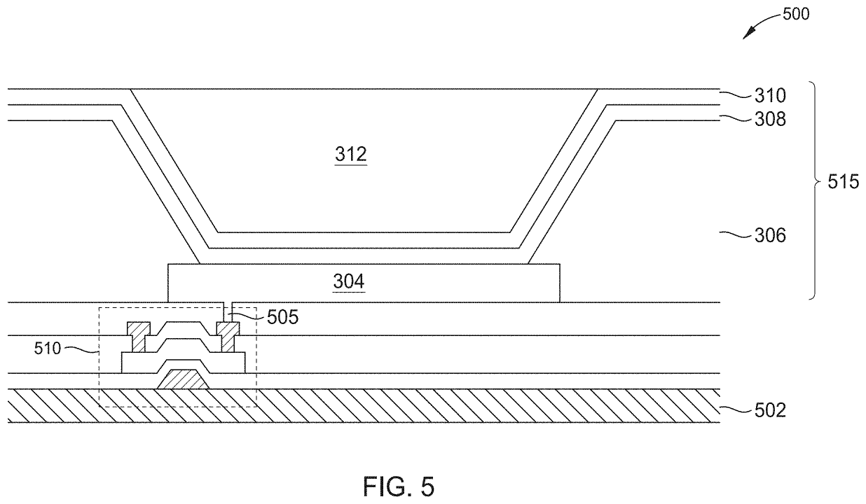

FIG. 5 shows a cross-section of an example pixel of a AMOLED structure 500 according to at least one embodiment of the present disclosure. The AMOLED structure can make use of the OLED structures described above having high optical out-coupling efficiency (e.g., example OLED structure 300). The AMOLED structure 500 has, at least, enhanced emission efficiency.

The example pixel of an AMOLED structure 500 includes a substrate 502. A thin film transistor (TFT) 510, such as a TFT driving circuit array, is disposed over and/or formed on at least a portion of the substrate 502. An interconnection 505 is disposed between the TFT 510 and at least a portion of the OLED 515 such that the TFT 510 can drive and control the OLED 515. The interconnection 505 is electrically coupled to the organic emitting unit 308 by the bottom electrode 304 and the interconnection 505 is electrically coupled to the TFT 510. Generally, the AMOLED structure 500 can be formed by first performing several lithography operations to create the TFT. After the TFT 510 is formed, a planar layer can be created on top of the TFT 510 such that the bottom electrode 304 can be deposited on the planar layer. Next, the OLED 515 can be formed on the bottom electrode 304 as described above such as by thermal evaporation in high vacuum or by other approaches such as ink-jet printing. The AMOLED structure 500 can include additional elements where applicable such as a backplane (TFT arrays), front plane (emission structure), thin film encapsulation (TFE), and polarizers. The AMOLED can additionally have a scanning line and a data line. The scanning line operates to turn on the pixel and the data line operates to write in the value to emit the light.

### EXAMPLES

The following examples are illustrative, but non-limiting, examples directed to one or more embodiments of the present disclosure.

### Example 1

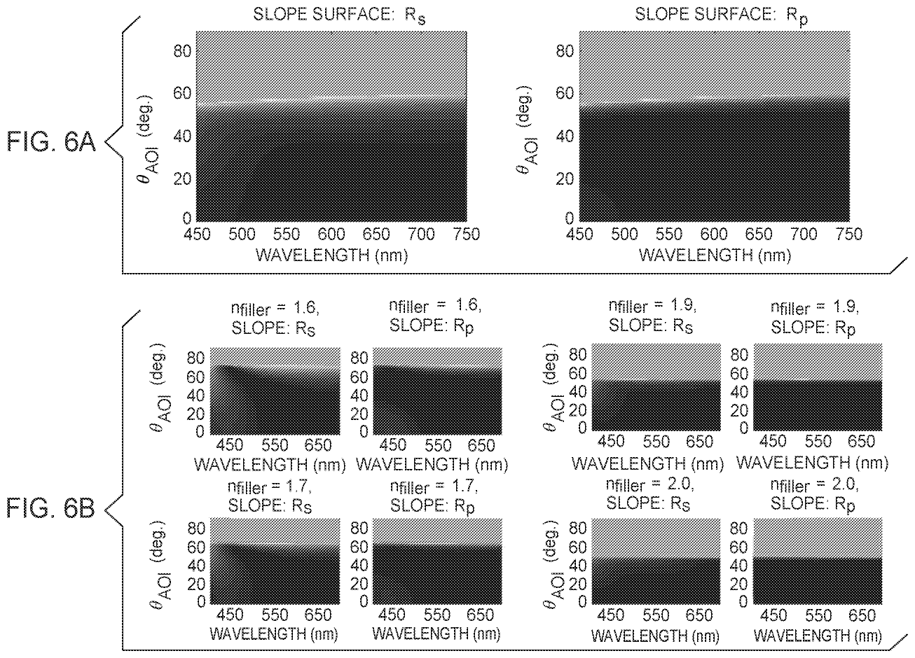

FIG. 6A shows an example PDL side-wall reflectivity for S-polarized light (Rₛ) and P-polarized light (Rₚ) versus varying wavelength and angle of incidence (AOI). For these examples, the refractive indices of the filler and the PDL are about 1.81 and about 1.52, respectively. The layer above filler and pixel is air with a refractive index of 1.0. The cut-off line is observed to be between the AOI of about 55 degrees and about 60 degrees, which is the critical angle of total internal reflection resulting from the difference of refractive indices of the filler (higher) and the pixel PDL (lower). This example illustrates that that the TIR can be strengthened by increasing the difference of between the refractive indices of the PDL and the filler. FIG. 6B shows examples indicating the reflectivity of a PDL side wall with various fillers of different refractive indices. The cut-off lines shift to a smaller AOI when using a filler having a higher refractive index values (thus a larger refractive index difference with the PDL).

### Example 2

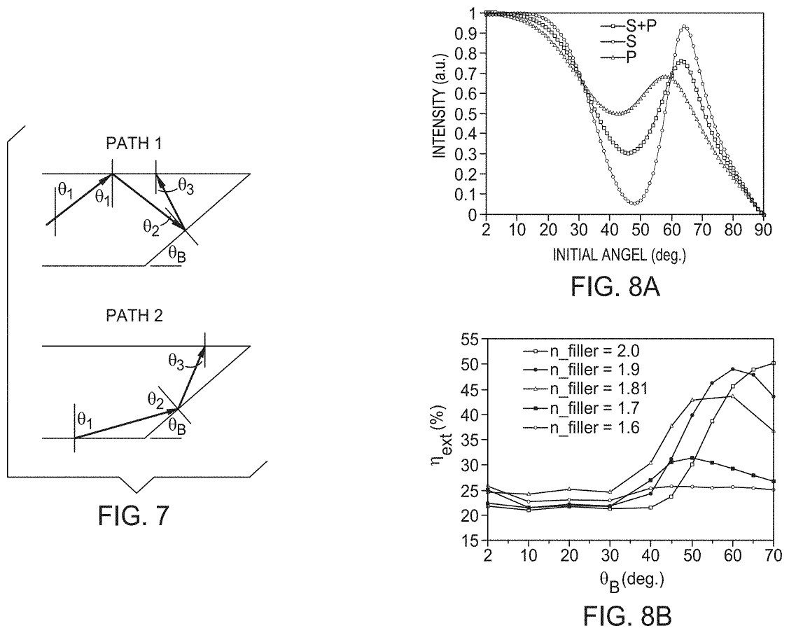

In order to avoid the loss of light penetrating into the PDL, the pixel structure can be designed to make the light reflect at the side to increase light extraction efficiency with the aid of total internal reflection phenomenon. In addition to the refractive index difference between the filler and the PDL, various structural parameters of pixels, such as the bank angle (θ_{B}) of the PDL and the height-to-width ratio of the pixel can have impact on the extraction. As shown in FIG. 7, when light is emitted from the organic emitting unit, the relation between the initial emission angle θ₁ (the emission angle related to the normal of bottom electrode 304) of the light incident and the bank angle θB of the PDL can be divided into two groups. H and W₁ are described above. θ₁ is the initial emission angle, θ₂ is the incident angle at the filler/PDL interface, and θ₃ is the incident angle to the upper interface of the filler after redirected by the PDL interface.

Path 1 satisfies the equation θ₁+θ_{B}≤90°, where the light is first incident on the horizontal interface between the filler and the layer above (e.g. air, referred to as the upper-filler interface). Path 2 is the light with θ₁+θ_{B}>90°, and the light is first incident on the oblique interface between the filler and the PDL (hereinafter referred to as the filler/PDL interface). To simplify the discussion, the transition from Path 1 to Path 2 among the processes is not included.

As shown in FIG. 7, the light of Path 1 and Path 2 can be analyzed in the following manner: Path 1 is the light that is first incident on the upper-filler interface. Since the bottom electrode should be parallel to the upper-filler interface, the light will have the same incident angle at upper-filler interface as the initial emission angle θ₁. Assuming the upper-interface possesses a critical angle θ_{c,filler} of total internal reflection from the refractive index difference of the filler and the material above filler. For an incident angle θ₁ smaller than θ_{c,filler}, light can be directly coupled externally. For rest of Path 1, the light experiences a total internal reflection at the interface and is reflected back to the filler/PDL interface. The geometric relation can define θ₂, which is the incident angle of light at the filler/PDL interface. Assuming the filler/PDL interface possesses a critical angle θ_{c,PDL} of total internal reflection from the refractive index difference of filler and PDL. If θ₂ is smaller than θ_{c,PDL}, most of the light will penetrate into the PDL and become a loss of light penetrating into the PDL. If θ₂ is greater than or equal to θ_{c,PDL}, then the light forms a total internal reflection at the filler/PDL interface and the light is reflected to the upper-filler interface. The geometric relation defines θ₃, which is the incident angle at the upper-filler interface after the light was reflected from the filler/PDL interface. Then, if θ₃ is smaller than the critical angle θ_{c,filler}, the light can be extracted out of filler smoothly, which is regarded as successful light emission/extraction. If θ₃ is greater than or equal to θ_{c,filler}, the light is still trapped in the pixel structure due to total internal reflection, which is considered as potential loss of light.

Path 2 is the light that is first incident on the filler/PDL interface. If θ₂ is smaller than θ_{c,PDL}, most of the light enters the pixel definition layer and is regarded as a loss of light penetrating into the PDL. If θ₂ is greater than or equal to θ_{c,PDL}, the light forms total internal reflection and is directed to the upper-filler interface. If the redirected light possesses a θ₃ that is smaller than θ_{c,filler} at the upper-filler interface, the light is smoothly coupled out of the filler. If θ₃ is greater than or equal to θ_{c,filler}, the light is still trapped in the pixel structure and is regarded as potential loss of light.

### Example 3

FIG. 8A is a graph showing luminous intensity versus initial emission angle (θ₁) of an example OLED device. S refers to the S-polarized emission, P refers to P-polarized emission, and S+P refers to the summary emission. The S+P summary emission has obvious peaks at the initial emission angles of about 0° and about 63°. The light with an initial emission angle of 0° doesn't experience total internal reflection and could be directly extracted out of filler/pixel. For the intensity peak at an initial emission angle of about 63° (θ₁), the incident angles at filler/PDL interface (θ₂) and at upper-PDL interface (θ₃) of the light are listed in Table 1 (positive and negative values represent the direction). From the values of incident angles θ₂ and θ₃ one can determine if the light experiences total internal reflection at the interface.

TABLE 1

| | Path 1 | | Path 2 | | | | |
|---|---|---|---|---|---|---|---|
| θ_{B} | 10° | 20° | 30° | 40° | 50° | 60° | 70° |
| θ₁ | 63° | 63° | 63° | 63° | 63° | 63° | 63° |
| θ₂ | 53° | 43° | 87° | 77° | 67° | 57° | 47° |
| θ₃ | −43° | −23° | 57° | 37° | 17° | −3° | −23° |

To avoid energy loss and make the light experience with total internal reflection at the filler/PDL interface, θ₂ is greater than or equal to θ_{c,PDL}, which is about 57° (assuming the filler possesses a refractive index of 1.81 and the PDL possesses a refractive index of 1.52, respectively). From Table 1, a PDL with bank angles smaller than 60° can meet the target. However, after being reflected at the filler/PDL interface, to avoid total internal reflection at the upper-filler interface so the light can be extracted out of filler/pixel, the incident angle θ₃ at the upper-filler interface should be smaller than θ_{c,filler}, which is about 34° (assuming the layer above filler is air with refractive index of 1.0 and the filler possesses a refractive index of 1.81, respectively). Accordingly, Table 1 shows that when θ_{B} falls between about 50° and about 60°, light extraction can be tuned. FIG. 8B summarizes the light extraction efficiency (ηₑₓₜ, in percent) versus different bank angles and different filler refractive indices. Higher light extraction efficiency was observed for bank angles from about 40° to about 70°, such as from about 50° to about 60°.

### Example 4

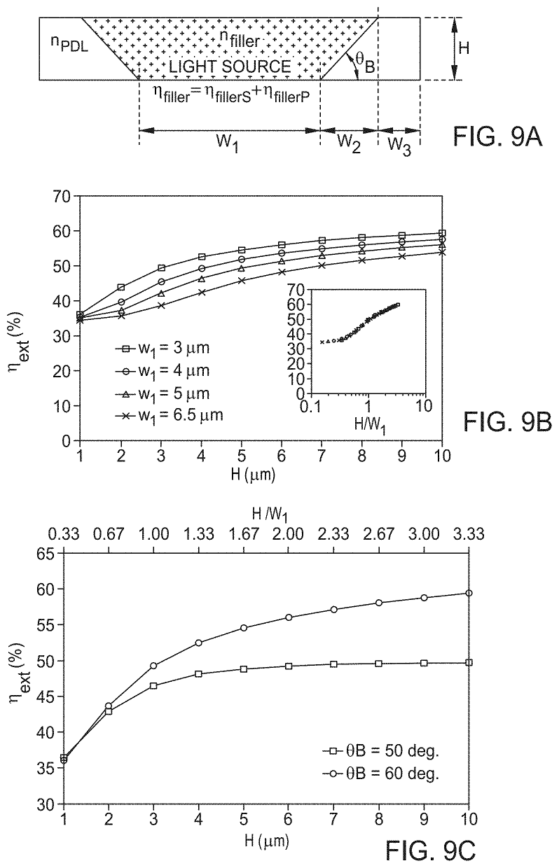

Further, the influence of the dimension parameters of pixel like height and width of pixel on the light extraction efficiency can be determined by simulation. The ratio of Path 1 to Path 2 is highly correlated to the height and width of the pixel structure and also to the ratio of the height to the width of the pixel structure. FIG. 9A and Table 2 show certain parameters used in the simulation and the simulation results are shown in FIG. 9B and FIG. 9C. For the parameters labeled in FIG. 9A, H is the height of pixel. It is the distance from the upper edge of filler to the bottom electrode layer. W₁ is the width of pixel opening, which is defined by the distance between lower PDL edges contacting with bottom electrode layer. W₂ is the horizontal distance of PDL incline surface. It can be determined from the horizontal distance from lower PDL edge contacting the bottom electrode layer to the upper edge of PDL where PDL becomes flat. W₂ can also be calculated from the height H and bank angle θ_{B} (W₂=H/tan(θ_{B}). n_{filler} and n_{PDL} are the refractive indices of filler material and PDL.

TABLE 2

| W₁ (μm) | W₂ (μm) | H (μm) | θ_{B} (deg.) | n_{PDL} | n_{filler} |
|---|---|---|---|---|---|
| 3 | H/tan(60°) | variable | 60 | 1.52 | 1.81 |
| 4 | | | | | |
| 5 | | | | | |
| 6 | | | | | |

As shown in FIG. 9B, in the case of different pixel widths, the light extraction efficiency is improved as the height of the pixel structure increases (with a fixed θ_{B}=60°). In addition, higher light out-coupling efficiency was observed with a smaller pixel width. Accordingly, when the entire aspect ratio (H/W₁) increases, the light extraction efficiency is improved.

The relation between extraction efficiency and height to width ratio can be further discussed in FIG. 9C. In FIG. 9C the pixel width is fixed at 3 μm and pixel height and bank angle (θ_{B}=50° or 60°) are variables. As the trend suggested, with a fixed pixel width, higher pixel height and thus larger H/W₁ ratio can lead to better extraction. A structure with a pixel defining layer possessing a low n refractive index than a refractive index of the filler and of the one or more layers of the organic emitting unit can lead to extraction efficiency improvement. The extraction efficiency can be tuned by properly designing the pixel dimension parameters like bank angle, pixel width, pixel height, and the height to width ratio, etc.

Structures and devices with improved light extraction efficiency and improved external quantum efficiency (EQE) are disclosed herein. The structures and devices overcome one or more deficiencies of conventional OLED structures and devices.

All documents described herein are incorporated by reference herein, including any priority documents and/or testing procedures to the extent they are not inconsistent with this text. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including.” Likewise whenever a composition, an element or a group of elements is preceded with the transitional phrase “comprising,” it is understood that we also contemplate the same composition or group of elements with transitional phrases “consisting essentially of,” “consisting of,” “selected from the group of consisting of,” or “is” preceding the recitation of the composition, element, or elements and vice versa.

The terms “over,” “under,” “between,” “on,” and other similar terms as used herein refer to a relative position of one layer with respect to other layers. As such, for example, one layer disposed over or under another layer may be directly in contact with the other layer or may have one or more intervening layers. Moreover, one layer disposed between layers may be directly in contact with the two layers or may have one or more intervening layers. In contrast, a first layer “on” a second layer is in contact with the second layer. The relative position of the terms does not define or limit the layers to a vector space orientation of the layers. The term “coupled” is used herein to refer to elements that are either directly connected or connected through one or more intervening elements.

For the purposes of this disclosure, and unless otherwise specified, all numerical values within the detailed description and the claims herein are modified by “about” or “approximately” the indicated value, and consider experimental error and variations that would be expected by a person having ordinary skill in the art. Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below.

While the foregoing is directed to examples of the present disclosure, other and further examples of the disclosure may be devised without departing from the basic scope thereof, and the scope thereof is determined by the claims that follow.

What is claimed is:

1. An electroluminescent device, comprising:
a plurality of pixels, each pixel of the plurality of pixels comprising:
a pixel defining layer;
an organic emitting unit disposed over at least a portion of the pixel defining layer, the organic emitting unit comprising one or more layers; and
a filler layer disposed over at least a portion of the organic emitting unit, wherein a refractive index of the pixel defining layer is lower than a refractive index of the filler layer and lower than a refractive index of the one or more layers of the organic emitting unit,
wherein each pixel of the plurality of pixels is isolated from the other pixels of the plurality of pixels.

2. The electroluminescent device of claim 1, wherein the organic emitting unit has a first surface, a second surface that lies at an angle relative to the first surface, and a third surface substantially parallel to the first surface.

3. The electroluminescent device of claim 1, further comprising a top electrode, the top electrode disposed over at least a portion of the organic emitting unit, the filler layer disposed over at least a portion of the top electrode.

4. The electroluminescent device of claim 3, wherein the top electrode comprises a transparent conductive oxide material, a semi-transparent conductive oxide material, a metal, a metal alloy, or a combination thereof.

5. The electroluminescent device of claim 1, further comprising a bottom electrode, the pixel defining layer disposed over at least a portion of the bottom electrode.

6. The electroluminescent device of claim 1, wherein the refractive index of the pixel defining layer is from about 1.0 to about 1.6 at a wavelength or wavelength range of a light emitted by the electroluminescent device.

7. The electroluminescent device of claim 1, wherein the refractive index of the one or more layers of the organic emitting unit is from about 1.3 to about 2.4 at a wavelength or wavelength range of a light emitted by the electroluminescent device.

8. The electroluminescent device of claim 1, wherein the refractive index of the filler layer is greater than about 1.6 at a wavelength or wavelength range of a light emitted by the electroluminescent device.

9. The electroluminescent device of claim 1, wherein the refractive index of the filler layer is greater than or equal to the refractive index of the one or more layers of the organic emitting unit.

10. The electroluminescent device of claim 1, wherein:
an angle of the pixel defining layer is from about 40° to about 70°;
an aspect ratio (H/W₁) is larger than about 0.01; or
a combination thereof.

11. An electroluminescent device, comprising:
a plurality of pixels, each pixel of the plurality of pixels comprising:
a pixel defining layer disposed over at least a portion of a bottom electrode;
an organic emitting unit disposed over at least a portion of the pixel defining layer, the organic emitting unit comprising one or more layers;
a top electrode disposed over at least a portion of the organic emitting unit; and
a filler layer disposed over at least a portion of the top electrode,
wherein:
a refractive index of the pixel defining layer is lower than a refractive index of the filler layer,
the refractive index of the pixel defining layer is lower than a refractive index of the one or more layers of the organic emitting unit,
the refractive index of the filler layer is greater than or equal to the refractive index of the one or more layers of the organic emitting unit, and
the top electrode comprises a transparent conductive oxide material, a semi-transparent conductive oxide material, a metal, a metal alloy, or a combination thereof, and
each filler layer of each pixel is isolated from the filler layer of the other pixels.

12. The electroluminescent device of claim 10, wherein the organic emitting unit has a first surface, a second surface that lies at an angle relative to the first surface, and a third surface substantially parallel to the first surface.

13. The electroluminescent device of claim 10, wherein the refractive index of the pixel defining layer is from about 1.0 to about 1.6 at a wavelength or wavelength range of a light emitted by the electroluminescent device.

14. The electroluminescent device of claim 10, wherein:
the refractive index of the one or more layers of the organic emitting unit is from about 1.3 to about 2.4 at a wavelength or wavelength range of a light emitted by the electroluminescent device;
the refractive index of the filler layer is greater than about 1.6 at a wavelength or wavelength range of a light emitted by the electroluminescent device; or
a combination thereof.

15. The electroluminescent device of claim 1, wherein:
an angle of the pixel defining layer is from about 40° to about 70°;
an aspect ratio (H/W₁) is larger than about 0.01; or
a combination thereof.

16. A display device, comprising:
a substrate;
a thin film transistor formed on the substrate;
an interconnection electrically coupled to the thin film transistor; and
an electroluminescent device electrically coupled to the interconnection, the electroluminescent device comprising:
a plurality of pixels, each pixel of the plurality of pixels comprising:
a pixel defining layer;
an organic emitting unit disposed over at least a portion of the pixel defining layer, the organic emitting unit comprising one or more layers; and
a filler layer disposed over at least a portion of the organic emitting unit, wherein a refractive index of the pixel defining layer is lower than a refractive index of the filler layer and lower than a refractive index of the one or more layers of the organic emitting unit, wherein each filler layer of each pixel is isolated from the filler layer of the other pixels.

17. The display device of claim 16, wherein the electroluminescent device further comprises a bottom electrode, the bottom electrode electrically coupled to the interconnection.

18. The display device of claim 16, wherein the refractive index of the filler layer is greater than or equal to a refractive index of the organic emitting unit.

19. The display device of claim 16, further comprising a top electrode, the top electrode disposed over at least a portion of the organic emitting unit, the filler layer disposed over at least a portion of the top electrode.

20. The display device of claim 16, wherein the organic emitting unit has a first surface, a second surface that lies at an angle relative to the first surface, and a third surface substantially parallel to the first surface.
